(19) United States
(12) Patent Application Publication
(10) Pub. No.: US 2007/0145006 A1
(43) Pub. Date: Jun. 28, 2007

(54) PLASMA ETCHING APPARATUS

(76) Inventor: Jin Ho Kim, Chungbuk (KR)

Correspondence Address: SHERR & NOURSE, PLLC, 620 HERNDON PARKWAY, SUITE 200, HERNDON, VA, 20170, US

(21) Appl. No.: 11/614,616

(22) Filed: Dec. 21, 2006

(30) Foreign Application Priority Data
Dec. 27, 2005 (KR) 10-2005-0130807

(51) Int. Cl. C23F 1/00; C23C 16/00

(52) U.S. Cl. 216/67; 118/723 I; 156/345.48

(57) ABSTRACT

Embodiments relate to a plasma etching apparatus that may include a lower chamber, an upper chamber installed on the upper side of the lower chamber, for providing a space in which plasma is generated, a dome section installed on the upper chamber, an electrostatic chuck installed in the lower chamber, for supporting a wafer, a first coil section installed in the dome section, for inductive coupling for plasma, a first bias power section applying a first bias to the first coil section, a second bias power section applying a second bias for inducing conductive coupling to the plasma to the rear side of the electrostatic chuck, a second coil section introduced between the electrostatic chuck and the dome section for distributing relative voltage drop by the first bias, and a third bias power section applying a third bias to the second coil section.

The present application claims priority under 35 U.S.C. 119 and 35 U.S.C. 365 to Korean Patent Application No. 10-2005-0130807 (filed on Dec. 27, 2005), which is hereby incorporated by reference in its entirety.

### BACKGROUND

In a process of manufacturing a semiconductor device, a plasma etching apparatus may be used in an etching process of patterning a material layer on a wafer. The plasma etching apparatus may use a dual plasma method and may include a first bias section to apply a source bias for generating plasma to an upper side of the process chamber and a second bias section to apply a back bias to increase the anisotropic etching characteristics to the rear side of a chuck.

However, according to a related art method, since the bias of a coil of a dome section may be considerably high, corrosion due to heating of the dome section may generate a source of particles.

Especially, in all products of below 0.18 μm, the process may be minute and the procedure may become longer. Therefore, as the process proceeds, particles may be dropped by an RF turn on-off to may generate a block between the steps.

### SUMMARY

Embodiments relate to a plasma etching apparatus.

Embodiments relate to a plasma etching apparatus that may be capable of preventing corrosion due to heating of a dome on an upper side of a chamber and prevents the generation of particles.

In embodiments, a plasma etching apparatus may include a lower chamber, an upper chamber installed on the upper side of the lower chamber, for providing a space in which plasma may be generated, a dome section installed on the upper chamber, an electrostatic chuck installed in the lower chamber, for supporting a wafer, a first coil section installed in the dome section, for inductive coupling for plasma, a first bias power section applying a first bias to the first coil section, a second bias power section applying a second bias for inducing conductive coupling to the plasma to the rear side of the electrostatic chuck, a second coil section introduced between the electrostatic chuck and the dome section for distributing relative voltage drop by the first bias, and a third bias power section applying a third bias to the second coil section.

### BRIEF DESCRIPTION OF THE DRAWINGS

FIG. 1 is an example schematic diagram illustrating a plasma etching apparatus according to embodiments.

### DETAILED DESCRIPTION OF THE INVENTION

According to embodiments, a relative voltage drop of a source bias may be distributed and may prevent contamination of an upper chamber and corrosion of a dome. Embodiments relate to a plasma etching apparatus that may use triple plasma and may remove a source of dropping particles.

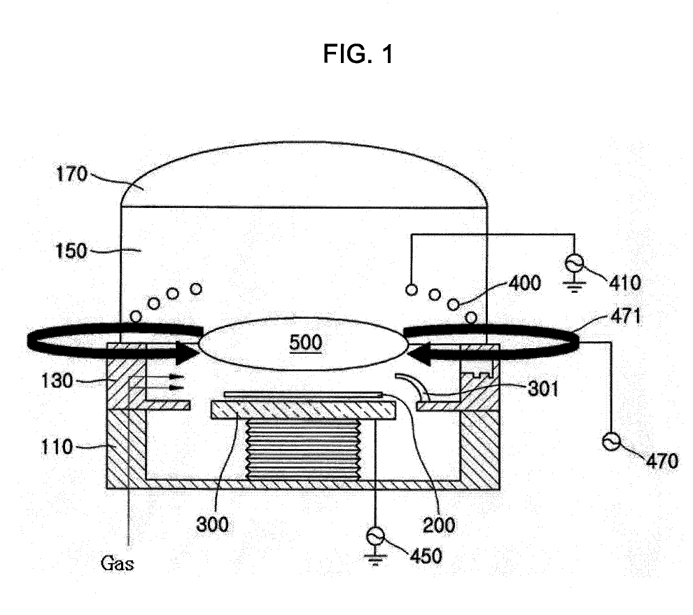

Referring to FIG. 1, a plasma etching apparatus according to embodiments may include lower chamber 110 and upper chamber 130 installed on an upper side of lower chamber 110 to provide a space in which plasma may be generated. The plasma etching apparatus may also include first dome section 150 and second dome section 170 installed on upper chamber 130.

Electrostatic chuck 300 that may support wafer 200 may be provided in lower chamber 110. Focus ring 301 may be provided around of electrostatic chuck 300. First coil section 400 of an induction coil may be installed in first dome section 150 for inductive coupling for plasma and a fan for cooling first dome section 150 or a matcher may be installed in second dome section 170 thereon.

First bias power section 410, which may apply first bias for inducing plasma 500 through an induction coil of first coil section 400 may include an RF generating section.

First bias power section 410 may apply an RF bias of approximately 11 to 13.3 MHz to first coil section 400.

Second bias power section 450, which may apply a second bias for inducing conductive coupling to plasma 500, may be provided on a rear side of electrostatic chuck 300. Second bias power section 450 may generate an RF bias of approximately 13.56 MHz.

Second coil section 471 may be provided between electrostatic chuck 300 and first dome section 150 and may distribute the relative voltage drop by the first bias. Third bias power section 470, which may apply a third bias to second coil section 471, may include an RF generator.

Second coil section 471 may include a single coil for distributing ionization by the inductive coupling.

The triple plasma constitution may prevent contamination of upper chamber 130 by distributing the relative voltage drop of a source bias. The principle of the dual plasma may be understood in that, when electrons obtaining power to maximize ionization lose the power after colliding with gaseous atoms, sufficient electrons exceeding the residual amount are supplied thereinto.

According to embodiments, atom decomposition by the inductive coupling may be distributed to a middle portion, by adding second coil section 471 for the dual plasma. This may prevent corrosion of the first dome section generated by heating upper chamber 130.

According to embodiments, since the plasma at the middle portion by second coil section 471 may be located at a position relatively close to a throttle valve, polymers generated by pumping may be removed relatively easily. Accordingly, contamination by particles dropping or block particles generated by second coil section 471 may be prevented.

According to embodiments, the corrosion of the dome section may be prevented by preventing heating of the upper chamber by a relatively large source bias. Accordingly, the source of the block particles may be effectively removed.

It will be apparent to those skilled in the art that various modifications and variations may be made to embodiments. Thus, it is intended that embodiments cover modifications and variations thereof within the scope of the appended claims. It is also understood that when a layer is referred to as being “on” or “over” another layer or substrate, it may be directly on the other layer or substrate, or intervening layers may also be present.

What is claimed is:

1. A device comprising:
a lower chamber;
an upper chamber installed on an upper portion of the lower chamber, and configured to provide a space in which plasma is generated;
a dome section installed on the upper chamber;
an electrostatic chuck installed in the lower chamber, and configured to support a wafer;
a first coil section installed in the dome section, and configured to provide inductive coupling for plasma;
a first bias power section configured to apply a first bias to the first coil section;
a second bias power section configured to apply a second bias for inducing conductive coupling to the plasma to the rear side of the electrostatic chuck;
a second coil section positioned between the electrostatic chuck and the dome section and configured to distribute a relative voltage drop by the first bias; and
a third bias power section configured to apply a third bias to the second coil section.

2. The device of claim 1, wherein the second coil section comprises a single coil to distribute ionization by the inductive coupling.

3. The device of claim 1, wherein the dome section comprises a first dome section and a second dome section.

4. The device of claim 3, wherein the first coil section of the induction coil is formed in the first dome section.

5. The device of claim 1, wherein the first bias power section is configured to apply an RF bias of approximately 11 to 13.3 MHz to the first coil section.

6. The device of claim 1, wherein the second bias power section is configured to generate an RF bias of approximately 13.56 MHz.

7. The device of claim 3, wherein the atom decomposition by inductive coupling is distributed to a middle portion by adding the second coil section that is configured to prevent corrosion of the first dome section by heating of the upper chamber.

8. A method comprising:
providing a chamber in which plasma is generated, the chamber having a dome section;
providing a platform to support a wafer;
applying a first bias to a first coil section by a first bias power section, to provide inductive coupling for the plasma, the first coil section being installed in the dome section;
applying a second bias in a second bias power section to induce conductive coupling to the plasma;
distributing a relative voltage drop by the first bias using a second coil section provided between an electrostatic chuck and the dome section; and
applying a third bias to the second coil section from a third bias power section.

9. The method of claim 8, wherein the second coil section comprises a single coil for distributing ionization by the inductive coupling.

10. The method of claim 8, wherein the first coil section is formed in the dome section and provides inductive coupling for the plasma.

11. The method of claim 8, further comprising applying an RF bias of approximately 11 to 13.3 MHz to the first coil section by the first bias power section.

12. The method of claim 8, further comprising generating an RF bias of approximately 13.56 MHz by the second bias power section.

13. A device, comprising:
a first coil section configured to provide inductive coupling to plasma in a semiconductor etching apparatus;
a first bias power section coupled to apply a first bias to the first coil section;
a second bias power section coupled to apply a second bias to induce conductive coupling to the plasma;
a second coil section coupled to distribute a relative voltage drop by the first bias; and
a third bias power section coupled to apply a third bias to the second coil section.

14. The device of claim 13, wherein the first bias power section is configured to apply an RF bias of approximately 11 to 13.3 MHz to the first coil section.

15. The device of claim 13, wherein the second bias power section is configured to generate an RF bias of approximately 13.56 MHz.
